(19) United States
(12) Patent Application Publication
(10) Pub. No.: US 2026/0271692 A1
(43) Pub. Date: Sep. 10, 2026

(54) IN-TRENCH QUALITY IMPROVEMENT OF SILICON-AND-OXYGEN-CONTAINING MATERIALS

(71) Applicant: Applied Materials, Inc., Santa Clara, CA (US)

(72) Inventors: Rui Wang, Sunnyvale, CA (US); Sukrant Dhawan, Santa Clara, CA (US); Supriya Ghosh, San Jose, CA (US); Susmit Singha Roy, Campbell, CA (US); Akhil Singhal, Portland, OR (US)

(73) Assignee: Applied Materials, Inc., Santa Clara, CA (US)

(21) Appl. No.: 19/072,150

(22) Filed: Mar. 6, 2025

(51) Int. Cl. H01L 21/768; H01L 21/02

(52) U.S. Cl. CPC H10W 20/096; H10P 14/6304; H10P 14/6532; H10P 14/6682; H10P 14/69215; H10W 20/097; H10W 20/098

(57) ABSTRACT

Exemplary methods of semiconductor processing may include i) providing a silicon-containing precursor to a processing region of a semiconductor processing chamber. A substrate may be disposed within the processing region and may define one or more features. The methods may include ii) contacting the substrate with the silicon-containing precursor to deposit a silicon-containing material that may extend within the features. The methods may include iii) providing an oxygen-containing precursor and a hydrogen-containing precursor to the processing region. The methods may include iv) forming plasma effluents of the oxygen-containing precursor and the hydrogen-containing precursor. The methods may include v) contacting the substrate with the plasma effluents of the oxygen-containing precursor and the hydrogen-containing precursor to convert the silicon-containing material to a silicon-and-oxygen-containing material. The contacting may increase Si—O—Si crosslinking in the silicon-and-oxygen-containing material. The methods may include repeating operations i through v to iteratively fill the features.

### TECHNICAL FIELD

The present technology relates to methods and components for semiconductor processing. More specifically, the present technology relates to methods for depositing silicon-containing materials in high-aspect ratio trenches with improved quality.

### BACKGROUND

Integrated circuits are made possible by processes which produce intricately patterned material layers on substrate surfaces. Producing patterned material on a substrate requires controlled methods for forming and removing material. As device sizes continue to reduce, features within the integrated circuits may get smaller and aspect ratios of structures may grow, and maintaining dimensions of these structures during processing operations may be challenged. Some processing may result in deposited materials that may be characterized by less than desirable quality. Developing materials that can satisfy quality standards may become more difficult as device sizes continue to scale.

Thus, there is a need for improved systems and methods that can be used to produce high quality devices and structures. These and other needs are addressed by the present technology.

### SUMMARY

Exemplary methods of semiconductor processing may include i) providing a silicon-containing precursor to a processing region of a semiconductor processing chamber. A substrate may be disposed within the processing region of the semiconductor processing chamber. The substrate may define one or more features along the substrate. The methods may include ii) contacting the substrate with the silicon-containing precursor. The contacting may deposit a silicon-containing material on the substrate. The silicon-containing material may extend within the one or more features along the substrate. The methods may include iii) providing an oxygen-containing precursor and a hydrogen-containing precursor to the processing region of the semiconductor processing chamber. The methods may include iv) forming plasma effluents of the oxygen-containing precursor and the hydrogen-containing precursor. The methods may include v) contacting the substrate with the plasma effluents of the oxygen-containing precursor and the hydrogen-containing precursor. The contacting may convert the silicon-containing material to a silicon-and-oxygen-containing material. The contacting may increase Si—O—Si crosslinking in the silicon-and-oxygen-containing material. The methods may include repeating operations i through v to iteratively fill the one or more features on the substrate with the silicon-and-oxygen-containing material.

In some embodiments, the silicon-containing precursor may be or include diisopropylaminosilane (DIPAS). The one or more features may be characterized by an aspect ratio of greater than or about 10:1. The oxygen-containing precursor may be or include diatomic oxygen (O₂). The hydrogen-containing precursor may be or include diatomic hydrogen (H₂). A flow rate ratio of the oxygen-containing precursor relative to the hydrogen-containing precursor may be between about 20:1 and about 4:1. A temperature within the semiconductor processing chamber may be maintained at greater than or about 300° C. A pressure within the semiconductor processing chamber may be maintained at less than or about 10 Torr.

Some embodiments of the present technology may encompass semiconductor processing methods. The methods may include i) providing a silicon-containing precursor to a processing region of a semiconductor processing chamber. A substrate may be disposed within the processing region of the semiconductor processing chamber. The substrate may define one or more features along the substrate. The methods may include ii) contacting the substrate with the silicon-containing precursor. The contacting may deposit a silicon-containing material on the substrate. The silicon-containing material may extend within the one or more features along the substrate. The methods may include iii) providing an oxygen-containing precursor to the processing region of the semiconductor processing chamber. The methods may include iv) contacting the substrate with the oxygen-containing precursor. The contacting may convert the silicon-containing material to a silicon-and-oxygen-containing material. The methods may include repeating operations i through iv to iteratively fill the one or more features on the substrate with the silicon-and-oxygen-containing material. The methods may include v) thermally treating the silicon-and-oxygen-containing material with the oxygen-containing precursor and a hydrogen-containing precursor. The treating may increase Si—O—Si crosslinking in the silicon-and-oxygen-containing material.

In some embodiments, treating the silicon-and-oxygen-containing material with the oxygen-containing precursor and the hydrogen-containing precursor may be performed for a period of time of greater than or about 5 minutes. Treating the silicon-and-oxygen-containing material with the oxygen-containing precursor and the hydrogen-containing precursor may reduce a wet etch rate (WER) of the silicon-and-oxygen-containing material by greater than or about 10%. The methods may include increasing a temperature within the processing region prior to treating the silicon-and-oxygen-containing material with the oxygen-containing precursor and the hydrogen-containing precursor. A temperature may be maintained at greater than or about 500° C. while treating the silicon-and-oxygen-containing material with the oxygen-containing precursor and the hydrogen-containing precursor. A pressure within the semiconductor processing chamber may be maintained at greater than or about 40 Torr while treating the silicon-and-oxygen-containing material with the oxygen-containing precursor and the hydrogen-containing precursor.

Some embodiments of the present technology may encompass semiconductor processing methods. The methods may include i) providing a silicon-containing precursor to a processing region of a semiconductor processing chamber. A substrate may be disposed within the processing region of the semiconductor processing chamber. The substrate may define one or more features along the substrate.

The methods may include ii) contacting the substrate with the silicon-containing precursor, wherein the contacting deposits a silicon-containing material on the substrate. The silicon-containing material may extend within the one or more features along the substrate. The methods may include iii) providing an oxygen-containing precursor and a hydrogen-containing precursor to the processing region of the semiconductor processing chamber. The methods may include iv) forming plasma effluents of the oxygen-containing precursor and the hydrogen-containing precursor. The methods may include v) contacting the substrate with the plasma effluents of the oxygen-containing precursor and the hydrogen-containing precursor. The contacting may convert the silicon-containing material to a silicon-and-oxygen-containing material. The contacting may increase Si—O—Si crosslinking in the silicon-and-oxygen-containing material. The methods may include repeating operations i through v to iteratively fill the one or more features on the substrate with the silicon-and-oxygen-containing material. The methods may include vi) thermally treating the silicon-and-oxygen-containing material with the oxygen-containing precursor and the hydrogen-containing precursor. The treating may further increase Si—O—Si crosslinking in the silicon-and-oxygen-containing material.

In some embodiments, the one or more features may be characterized by an aspect ratio of greater than or about 30:1. A flow rate ratio of the oxygen-containing precursor relative to the hydrogen-containing precursor at operation iii) may be between about 20:1 and about 4:1. The methods may include, subsequent to filling the one or more features on the substrate with the silicon-and-oxygen-containing material, increasing a temperature within the processing region. The methods may include, subsequent to filling the one or more features on the substrate with the silicon-and-oxygen-containing material, increasing a pressure within the processing region. Subsequent to thermally treating the silicon-and-oxygen-containing material with the oxygen-containing precursor and the hydrogen-containing precursor, the silicon-and-oxygen-containing material may be characterized by a wet etch rate (WER) of less than or about 12 nm/min.

Such technology may provide numerous benefits over conventional systems and techniques. For example, embodiments of the present technology may reduce the void or seam size applicable to a number of substrate features. Additionally, the present technology may produce silicon-and-oxygen-containing materials for gap filling applications, as well as any other application, for which materials may be characterized by increased quality, which may be correlated with wet etch rate (WER). These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 shows operations in a semiconductor processing method according to some embodiments of the present technology.

FIGS. 3A-3C show exemplary schematic cross-sectional structures in which material layers are included and produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As device sizes continue to shrink, many material layers may be reduced in thickness and size to scale devices. Features across semiconductor structures may be reduced in size, and aspect ratios of the features may increase. As the aspect ratios of the features increase, deposition processes may produce materials with reduced quality and/or uniformity.

Conventional technologies, such as operations associated with 3D NAND or 3D dynamic random access memory (DRAM), have struggled to produce materials for high aspect ratio gap fill applications that may be characterized by uniform quality along an entire length or depths of a feature being filled. Poorer quality material, such as silicon-and-oxygen-containing material, may be present towards lower portions of the features. The poorer quality may be indicated by an increased wet etch rate (WER) of the material. During downstream processing, a full length of the feature may be exposed to multiple wet or vapor-based etchants. In order for the devices to perform as intended and desired, it is critical for the top-to-bottom etch rate of the material be uniform. Conventional technologies have struggled with forming materials that have uniform properties, such as quality, along the full length of the feature.

The present technology may overcome these issues using multiple solutions. For example, the present technology may introduce a reactive hydrogen-containing precursor with the oxygen-containing precursor that may be used to convert silicon-containing materials to silicon-and-oxygen-containing materials. Incorporating a reactive hydrogen-containing precursor may increase Si—O—Si crosslinking in the silicon-and-oxygen-containing material, which may reduce WER and indicate improved quality. Alternatively, a post-deposition treatment using an oxygen-containing precursor and/or a hydrogen-containing precursor, which may be the same as precursors previously used to form the silicon-and-oxygen-containing materials, to further treat the material and increase Si—O—Si crosslinking. Some embodiments may include both introducing the reactive hydrogen-containing precursor with the oxygen-containing precursor that may be used to convert silicon-containing materials to silicon-and-oxygen-containing materials and the post-deposition treatment to improve the quality of the materials. Additionally, the present technology may provide silicon-and-oxygen-containing materials with increased uniformity, which may be indicated by a more consistent WER along the entire length or depth of the materials. As such, the present technology may reduce and/or prevent problems in any following integration processes and/or defects in the final devices.

Although the remaining disclosure will routinely identify specific deposition processes utilizing the disclosed technology, and will describe one type of semiconductor processing chamber, it will be readily understood that the processes described may be performed in any number of semiconductor processing chambers. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

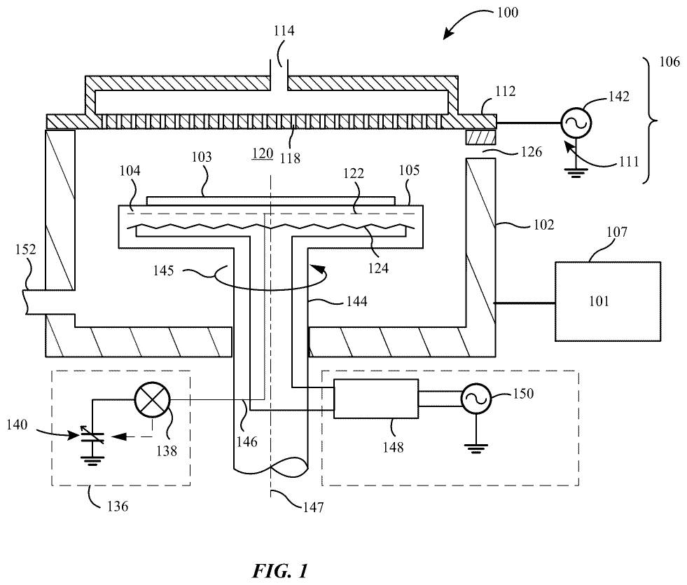

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, as indicated by the arrow 145, along an axis 147, where a shaft 14a4 of the substrate support 104 may be locate, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the second electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the first circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the circuit 136 in a closed loop. A set point for current or voltage, depending on the type of sensor used, may be installed in each sensor, and the sensor may be provided with control software that determines an adjustment to the respective electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

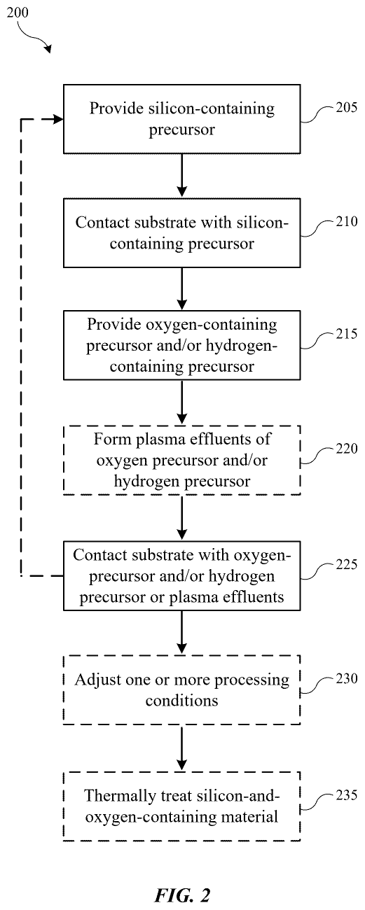

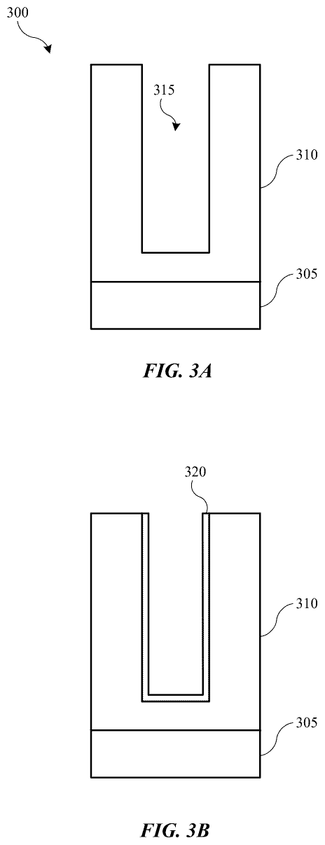

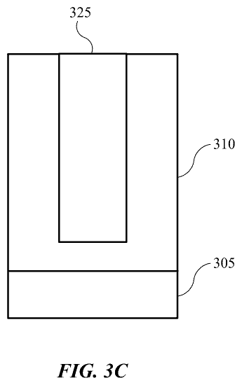

FIG. 2 shows exemplary operations in a processing method 200 according to some embodiments of the present technology. The method 200 may be performed in a variety of processing chambers, including the semiconductor processing chamber 100 described above, as well as any other chambers, in which the operations may be performed. Method 200 may include one or more operations prior to the initiation of the method 200, including front-end processing, deposition, etching, polishing, cleaning, or any other operations that may be performed prior to the described operations. The method 200 may include a number of optional operations, which may or may not be specifically associated with some embodiments of methods according to embodiments of the present technology. For example, many of the operations are described in order to provide a broader scope of the processes performed, but are not critical to the technology, or may be performed by alternative methodology as will be discussed further below. Method 200 may describe operations shown schematically in FIGS. 3A-3C, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may or may not involve optional operations to develop the semiconductor structure to a particular fabrication operation. It is to be understood that method 200 may be performed on any number of semiconductor structures or substrates 305, as illustrated in FIG. 3A, including exemplary structure 300 on which one or more silicon-containing materials may be formed. As illustrated in FIG. 3A, substrate 305 may be processed to form one or more features 315, which may be recessed, such as trenches, apertures, or any other structure in semiconductor processing. Substrate 305 may be any number of materials, such as a base wafer or substrate 305 made of silicon or silicon-containing materials, other substrate 305 materials, as well as one or more materials that may be formed overlying the substrate 305 during semiconductor processing. For example, in some embodiments the substrate 305 may be processed to include one or more materials or structures for semiconductor processing. Substrate 305 may be or include a dielectric material, such as an oxide or nitride of any number of materials. In embodiments, one or more layers of material, which may be encompassed by the illustrated layer of material 310, may be deposited on the substrate 305. In embodiments, the layer of material may be a silicon-containing material, such as silicon. Alternatively, the layer of material 310 may be a stack of alternating layers, such as layers of one or more silicon-containing materials. For example, the stack of alternating layers may be alternating layers of a first silicon-containing material and a second silicon-containing material. The first and second silicon-containing material may each be selected from silicon, a silicon-and-oxygen-containing material, a silicon-and-nitrogen-containing material, a silicon-and-germanium-containing material, or any other silicon-containing material.

As shown, one or more features 315 may be defined in the layer of material 310 and/or substrate 305, such as a trench, aperture, or other recessed feature. While illustrated with parallel sidewalls, it is contemplated that the features 315 may be characterized by non-parallel sidewalls, such as tapered sidewalls. The aspect ratio of the features 315, or the ratio of the depth of the feature relative to the width or diameter of the feature formed, may be greater than or about 10:1, and may be greater than or about 15:1, greater than or about 20:1, greater than or about 25:1, greater than or about 30:1, greater than or about 35:1, greater than or about 40:1, greater than or about 45:1, greater than or about 50:1, greater than or about 75:1, greater than or about 100:1, or more. Although only one feature 315 is shown, it is to be understood that exemplary structures may have any number of features 315 defined along the structure 300 according to embodiments of the present technology.

Additionally, the features 315 may be characterized by narrow widths or diameters across the feature including between two sidewalls, such as a dimension less than or about 250 nm, and may be characterized by a width across the feature of less than or about 200 nm, less than or about 150 nm, less than or about 100 nm, less than or about 90 nm, less than or about 80 nm, less than or about 70 nm, less than or about 60 nm, less than or about 50 nm, less than or about 40 nm, less than or about 30 nm, or less. Further, the features may be characterized by a depth of greater than or about 100 nm, and may be characterized by a depth of greater than or about 250 nm, greater than or about 500 nm, greater than or about 750 nm, greater than or about 1 μm, greater than or about 1.5 μm, greater than or about 2 μm, greater than or about 2.5 μm, greater than or about 3 μm, greater than or about 3.5 μm, greater than or about 4 μm, greater than or about 4.5 μm, greater than or about 5 μm, greater than or about 5.5 μm, or more.

At operation 205, the method 200 may include providing a silicon-containing precursor to the processing region of the semiconductor processing chamber. The silicon-containing precursor may be provided to the same processing region of the semiconductor processing chamber to perform operations prior to the initiation of the method 200. At operation 210, the method 200 may include contacting the substrate 305 with the silicon-containing precursor. If present, the silicon-containing precursor may contact the one or more layers of material 310 and/or the substrate 305. As illustrated in FIG. 3B, the contacting may deposit a silicon-containing material on the substrate 305 and the one or more layers of material 310, if present.

Silicon-containing precursors that may be used in method 200 may be or include any number of silicon-containing precursors. For example, the silicon-containing precursor may be or include silane (SiH₄), dislane (Si₂H₆), silicon tetrachloride (SiCl₄), tetraethyl orthosilicate (TEOS), diisopropylaminosilane (DIPAS), or any other oxygen-containing precursor used or useful in semiconductor processing, such as one able to form, for example, a silicon oxide (SiO), a silicon nitride (SiN), or a silicon carbide (SiC) material. In some embodiments, along with the silicon-containing precursor, one or more additional precursors may be delivered, such as a hydrogen-containing precursor as well as one or more carrier or inert gases, such as argon (Ar), helium (He), or xenon (Xe), for example. Although higher-order silanes may be used in embodiments of the present technology, higher-order silanes may undesirably result in increased hydrogen content in the as-deposited material, which may lead to outgassing in subsequent operations.

A flow rate of the silicon-containing precursor may be sufficient to expose the layer of material 310 to silicon material and begin forming silicon material. In embodiments, the flow rate of the silicon-containing precursor may be greater than or about 1 sccm, and may be greater than or about 5 sccm, greater than or about 10 sccm, greater than or about 25 sccm, greater than or about 50 sccm, greater than or about 100 sccm, greater than or about 250 sccm, greater than or about 500 sccm, or more.

As previously discussed, at operation 210, the method 200 may include contacting the substrate with the silicon-containing precursor. If present, the silicon-containing precursor may contact the one or more layers of material 310 and/or the substrate 305. The contacting may deposit a silicon-containing material on the substrate 305 and the one or more layers of material 310, if present. The silicon-containing material 320 may extend along any and/or all exposed surfaces along the substrate 305, when exposed, as well as any other incorporated materials, such as the one or more layers of material 310. As illustrated in FIG. 3B, the silicon-containing material 320 may be deposited on sidewalls and a bottom of the features 315. During operation 210, growth may occur inward within the features 315 from the sidewalls defining the features 315.

At operation 215, method 200 may include providing an oxygen-containing precursor and/or a hydrogen-containing precursor to the processing region of the semiconductor processing chamber. Prior to providing the oxygen-containing precursor and/or the hydrogen-containing precursor, method 200 may include halting a flow of the silicon-containing precursor provided at operation 205. Further, the processing region may be purged prior to providing the oxygen-containing precursor and/or the hydrogen-containing precursor. The oxygen-containing precursor and/or the hydrogen-containing precursor may be provided to the same processing region of the semiconductor processing chamber to perform earlier operations of the method 200. Method 200 may include forming plasma effluents of the oxygen-containing precursor and/or the hydrogen-containing precursor at optional operation 220. Method 200 may include contacting the substrate 305 with the oxygen-containing precursor and/or the hydrogen-containing precursor or, if formed, plasma effluents thereof at operation 225.

Oxygen-containing precursors that may be used in method 200 may be or include any number of oxygen-containing precursors. For example, the oxygen-containing precursor may be or include diatomic oxygen (O₂), ozone (O₃), water or steam (H₂O), or any other oxygen-containing precursor used or useful in semiconductor processing, such as one able to form, for example, a SiO material. Hydrogen-containing precursors that may be used in method 200 may be or include any number of hydrogen-containing precursors. For example, the hydrogen-containing precursor may be or include diatomic hydrogen (H₂), ammonia (NH₃), H₂O, or any other hydrogen-containing precursor used or useful in semiconductor processing. In some embodiments, along with the oxygen-containing precursor and/or the hydrogen-containing precursor, one or more additional precursors may be delivered, such as one or more carrier or inert gases, such as Ar, He, or Xe, for example.

If formed, the plasma effluents of the oxygen-containing precursor and/or the hydrogen-containing precursor may be formed at a plasma power of greater than or about 1,000 W. At reduced plasma power, increased dissociation of the oxygen-containing precursor may result, which may reduce the rate at which the silicon-containing material 320 is oxidized to silicon-and-oxygen-containing material 325. As such, the plasma effluents of the oxygen-containing precursor and/or the hydrogen-containing precursor may be formed at a plasma power of greater than or about 1,250 W, greater than or about 1,500 W, greater than or about 1,600 W, greater than or about 1,700 W, greater than or about 1,800 W, greater than or about 1,900 W, greater than or about 2,000 W, greater than or about 2,250 W, greater than or about 2,500 W, or more. However, to limit dissociation and potential bombardment, the plasma effluents of the oxygen-containing precursor and/or the hydrogen-containing precursor may be formed at a plasma power of less than or about 3,000, and may be formed at less than or about 2,750 W, less than or about 2,500 W, less than or about 2,400 W, less than or about 2,400 W, less than or about 2,300 W, less than or about 2,200 W, less than or about 2,100 W, less than or about 2,000 W, or less.

As previously discussed, at operation 225, method 200 may include contacting the substrate with the oxygen-containing precursor and/or the hydrogen-containing precursor or, if formed, plasma effluents of the oxygen-containing precursor and/or the hydrogen-containing precursor. As illustrated in FIG. 3C, the contacting may convert at least a portion of the silicon-containing material 320 to a silicon-and-oxygen-containing material 325. Depending on a dimension of the features 315, the oxygen-containing precursor or, if formed plasma effluents thereof may not be able to fully diffuse the entire length or depth of the features 315. As such, the silicon-and-oxygen-containing material 325 toward bottom portions of the features 315 may have reduced Si—O—Si crosslinking compared to upper portions of the features 315. However, by including the hydrogen-containing precursor, and as further discussed below, increased Si—O—Si crosslinking along the entire length or depth of the features 315 may result.

In embodiments, a flow rate of the oxygen-containing precursor may be greater than or about 0.1 slm, greater than or about 0.5 slm, greater than or about 1 slm, greater than or about 1.2 slm, greater than or about 1.4 slm, greater than or about 1.6 slm, greater than or about 1.8 slm, greater than or about 2 slm, greater than or about 2.2 slm, greater than or about 2.4 slm, greater than or about 2.6 slm, greater than or about 2.8 slm, greater than or about 3 slm, or more. The flow rate of the oxygen-containing precursor may be adequate to oxidize the silicon-containing material 320 and form silicon-and-oxygen-containing material 325. At increased flow rates of the oxygen-containing precursor, a portion of the silicon-containing precursor may not react with the silicon-containing material 320 and may be pumped out of the processing region. As such, the flow rate of the oxygen-containing precursor may be less than or about 4 slm, and may be less than or about 3.8 slm, less than or about 3.6 slm, less than or about 3.4 slm, less than or about 3.2 slm, less than or about 3 slm, less than or about 2.8 slm, less than or about 2.6 slm, less than or about 2.4 slm, less than or about 2.2 slm, less than or about 2 slm, or less.

Depending on the dimensions of the features 315, a density of the oxygen-containing precursor or, if formed, plasma effluents of the oxygen-containing precursor may reduce towards a bottom portion of the features 315. As such, conversion of the silicon-containing material 320 to the silicon-and-oxygen-containing material 325 may not be as uniform along an entire length or depth of the features 315. With reduced conversion towards the bottom portion of the features 315, the silicon-containing material 320, if unconverted, or resultant silicon-and-oxygen-containing material 325, if incompletely converted, may be characterized by a reduced quality, which may be based on wet etch rate (WER) of the silicon-containing material 320, if unconverted, or resultant silicon-and-oxygen-containing material 325. An increased WER of the silicon-containing material 320, if unconverted, or resultant silicon-and-oxygen-containing material 325 may be due to the presence of hydroxyl (—OH) groups and/or reduced Si—O—Si crosslinking. To increase uniformity and quality, method 200 may include providing the hydrogen-containing precursor with the oxygen-containing precursor. The hydrogen-containing precursor may better diffuse the entire length or depth of the features 315 than the oxygen-containing precursor. The hydrogen-containing precursor may form additional —OH groups in the silicon-containing material 320, if unconverted, or resultant silicon-and-oxygen-containing material 325, which may lead to increased Si—O—Si crosslinking. The increased Si—O—Si crosslinking may reduce WER of the silicon-and-oxygen-containing material 325, indicating a higher quality material.

In embodiments, a flow rate of the hydrogen-containing precursor may be greater than or about 0.01 slm, greater than or about 0.05 slm, greater than or about 0.1 slm, greater than or about 0.12 slm, greater than or about 0.14 slm, greater than or about 0.16 slm, greater than or about 0.18 slm, greater than or about 0.2 slm, or more. At increased flow rates of the hydrogen-containing precursor, hydrogen content of the silicon-containing material 325 may undesirably increase. To control hydrogen incorporation, the flow rate of the hydrogen-containing precursor may be less than or about 0.4 slm, and may be less than or about 0.35 slm, less than or about 0.3 slm, less than or about 0.28 slm, less than or about 0.26 slm, less than or about 0.24 slm, less than or about 0.22 slm, less than or about 0.2 slm, or less.

In embodiments, a flow rate ratio of the oxygen-containing precursor relative to the hydrogen-containing precursor may be between about 20:1 and about 4:1. At reduced flow rate ratios, such as flow rate ratios less than 20:1, insufficient hydrogen may be present and may not interact with the silicon-and-oxygen-containing material 320 increasing Si—O—Si crosslinking. As such, the flow rate ratio of the oxygen-containing precursor relative to the hydrogen-containing precursor may be greater than or about 18:1, and may be greater than or about 16:1, greater than or about 14:1, greater than or about 12:1, greater than or about 10:1, greater than or about 8:1, greater than or about 6:1, greater than about 4:1, or more. Conversely, at increased flow rate ratios, excessive hydrogen may be incorporated into the silicon-and-oxygen-containing material 325, as previously discussed, which may affect material properties and/or result in hydrogen outgassing during subsequent processing. As such, the flow rate ratio of the oxygen-containing precursor relative to the hydrogen-containing precursor may be less than or about 6:1, and may be less than or about 8:1, less than or about 10:1, less than or about 12:1, less than or about 14:1, less than or about 16:1, less than or about 18:1, less than or about 20:1, or less. In embodiments, the flow rate ratio of the oxygen-containing precursor relative to the hydrogen-containing precursor may be between about 15:1 and about 5:1, or between about 12:1 and about 8:1.

Operations 205 through 225 may be repeated to iteratively fill the one or more features 315 on the substrate 305 with the silicon-and-oxygen-containing material 325. For example, operations 205-225 may be a single cycle of an atomic layer deposition (ALD) process or plasma-enhanced ALD (PEALD) process. As such, operations 205 through 235 may be repeated numerous times to form the silicon-and-oxygen-containing material 325. That is, the silicon-containing precursor and the oxygen-containing precursor, optionally with the hydrogen-containing precursor, may be provided as a series of sequential, non-overlapping pulses. Between the pulses, the processing region may be purged, such that any remaining precursor is removed prior to providing the next precursor. In embodiments, operations 205 through 225 may be repeated, depending on dimensions of the features 315, for greater than or about 10 cycles, greater than or about 20 cycles, greater than or about 30 cycles, greater than or about 40 cycles, greater than or about 50 cycles, greater than or about 75 cycles, greater than or about 100 cycles, greater than or about 125 cycles, greater than or about 150 cycles, greater than or about 175 cycles, greater than or about 200 cycles, or more to iteratively fill the one or more features 315 on the substrate 305 with the silicon-and-oxygen-containing material 325. Between FIGS. 3B and 3C, numerous cycles of operations 205 through 225 may performed to iteratively fill the one or more features 315 with silicon-and-oxygen-containing material 325.

At optional operation 230, method 200 may include adjusting one or more processing conditions. The processing conditions may be adjusted to transition from a bulk deposition of the silicon-and-oxygen-containing material 325 to a treatment of the silicon-and-oxygen-containing material 325. The one or more processing conditions that may be adjusted include, but are not limited to, temperature, pressure, plasma power, or any other processing condition. For example, the temperature may be increased from a first temperature to a second temperature. The pressure may be increased from a first pressure to a second pressure. The plasma power may be halted, such that any plasma in the processing region is extinguished. Prior to the treatment of the silicon-and-oxygen-containing material 325, the processing region may be made plasma-free and may be maintained plasma-free for the treatment. Further, an oxygen-containing precursor and/or a hydrogen-containing precursor may be provided after adjusting one or more processing conditions at optional operation 230. However, method 200 may include adjusting flow rates of an oxygen-containing precursor and/or a hydrogen-containing precursor, such as increasing either or both flow rates and/or a flow rate ratio.

After filling the one or more features 315 on the substrate 305 with the silicon-and-oxygen-containing material 325, method 200 may include treating the silicon-and-oxygen-containing material 325 at optional operation 235. Even with the addition of the hydrogen-containing precursor at operation 215, the resultant silicon-and-oxygen-containing material 325 may still be characterized by a less than desirable quality and/or uniformity. Along the entire length or depth of the features 315, missing Si—O—Si crosslinking or the presence of —OH groups may be present. As such, the treatment at optional operation 235 may further improve quality and/or uniformity of the silicon-and-oxygen-containing material.

The treatment at optional operation may include providing an oxygen-containing precursor and a hydrogen-containing precursor to the processing region and contacting the substrate 305, including the silicon-and-oxygen-containing material 325, with the precursors. The oxygen-containing precursor and the hydrogen-containing precursor provided for the treatment at optional operation 235 may be any of the precursors used at operation 215. Additionally, the oxygen-containing precursor and the hydrogen-containing precursor provided for the treatment at optional operation 235 may each be the same or may be different from the oxygen-containing precursor and the hydrogen-containing precursor provided at operation 215. In one exemplary embodiment, the oxygen-containing precursor may be or include O₂ and the hydrogen-containing precursor may be or include H₂.

In embodiments, and as previously discussed, the flow rate of the oxygen-containing precursor and the hydrogen-containing precursor at optional operation 235 may be increased relative to operation 215. For example, a flow rate of the oxygen-containing precursor at optional operation 235 may be greater than or about 3 slm, and may be greater than or about 4 slm, greater than or about 5 slm, greater than or about 5.5 slm, greater than or about 6 slm, greater than or about 6.5 slm, greater than or about 7 slm, greater than or about 7.5 slm, greater than or about 8 slm, greater than or about 8.5 slm, greater than or about 9 slm, or more. Similarly, a flow rate of the hydrogen-containing precursor at optional operation may be greater than or about 0.5 slm, and may be greater than or about 0.75 slm, greater than or about 1 slm, greater than or about 1.25 slm, greater than or about 1.5 slm, greater than or about 1.75 slm, greater than or about 2 slm, greater than or about 2.25 slm, or more.

Additionally, a flow rate ratio of the oxygen-containing precursor relative to the hydrogen-containing precursor at optional operation 235 may be increased relative to operation 215. In embodiments, the flow rate ratio of the oxygen-containing precursor relative to the hydrogen-containing precursor may be greater than or about 10:1, greater than or about 9:1, greater than or about 8:1, greater than or about 7:1, greater than or about 6:1, greater than or about 5:1, greater than about 4:1, or more. However, again to limit hydrogen incorporation in the silicon-and-oxygen-containing material 325, the flow rate ratio of the oxygen-containing precursor relative to the hydrogen-containing precursor at optional operation 235 may be less than or about 3:1, and may be less than or about 7:2, less than or about 4:1, less than or about 9:2, less than or about 5:1, less than or about 6:1, or less.

Similar to operation 225, the hydrogen-containing precursor may form additional —OH groups in the silicon-containing material 320, if unconverted, or resultant silicon-and-oxygen-containing material 325, which may lead to increased Si—O—Si crosslinking at optional operation 235. The increased Si—O—Si crosslinking may further reduce WER of the silicon-and-oxygen-containing material 325, indicating a higher quality material.

In embodiments, treating the silicon-and-oxygen-containing material 325 may be a thermal treatment, such that no plasma is provided to the processing region or formed in the processing region during optional operation 235. To thoroughly treat the silicon-and-oxygen-containing material 325, method 200 may include treating the silicon-and-oxygen-containing material 325 with the oxygen-containing precursor and the hydrogen-containing precursor for a period of time of greater than or about 5 minutes, and may include treating the silicon-and-oxygen-containing material 325 for greater than or about 10 minutes, greater than or about 15 minutes, greater than or about 20 minutes, greater than or about 25 minutes, greater than or about 30 minutes, greater than or about 35 minutes, greater than or about 40 minutes, greater than or about 45 minutes, greater than or about 50 minutes, greater than or about 55 minutes, greater than or about 1 hour, or more.

Temperature may impact operations of the present technology. For example, the method 200 may be performed at a temperature greater than or about 300° C., and may be performed at a temperature greater than or about 325° C., greater than or about 350° C., greater than or about 375° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., or more. Conversely, the method 200 may be performed at a temperature less than or about 700° C., and may be performed at a temperature less than or about less than or about 675° C., less than or about 650° C., less than or about 625° C., less than or about 600° C., less than or about 575° C., less than or about 550° C., less than or about 525° C., less than or about 500° C., less than or about 475° C., less than or about 450° C., less than or about 425° C., less than or about 400° C., less than or about 375° C., less than or about 350° C., less than or about 325° C., less than or about 300° C., or less. The temperature may be maintained in any of these ranges throughout method 200. While temperature may be maintained constant throughout method 200, it is also contemplated that temperature may be adjusted during operations of method 200. For example, and as previously discussed, method 200 may include increasing the temperature from the first temperature to the second temperature at optional operation 230. An increased temperature, such as greater than or about 550° C. or any other range previously discussed, may benefit Si—O—Si crosslinking during the treatment at optional operation 235.

Pressure may also impact operations of the present technology. For example, the method 200 may be performed at a pressure greater than or about 1 Torr, and may be performed at greater than or about 2 Torr, greater than or about 3 Torr, greater than or about 4 Torr, greater than or about 5 Torr, greater than or about 10 Torr, greater than or about 15 Torr, greater than or about 20 Torr, greater than or about 25 Torr, greater than or about 30 Torr, greater than or about 35 Torr, greater than or about 40 Torr, greater than or about 45 Torr, greater than or about 50 Torr, greater than or about 55 Torr, greater than or about 60 Torr, or more. Conversely, the method 200 may be performed at a pressure less than or about 60 Torr, and may be performed at a pressure less than or about 50 Torr, less than or about 40 Torr, less than or about 30 Torr, less than or about 25 Torr, less than or about 20 Torr, less than or about 15 Torr, less than or about 10 Torr, less than or about 9 Torr, less than or about 8 Torr, less than or about 7 Torr, less than or about 6 Torr, less than or about 5 Torr, less than or about 4 Torr, or less. Similar to temperature, to limit pressure adjustments in the semiconductor processing chamber, pressure may be maintained constant throughout method 200. However, it is also contemplated that pressure may be adjusted between operations of method 200. For example, and as previously discussed, method 200 may include increasing the pressure from the first pressure to the second pressure at optional operation 230. An increased pressure, such as greater than or about 30 Torr or any other range previously discussed, may benefit Si—O—Si crosslinking during the treatment at optional operation 235.

As previously discussed, the present technology may provide silicon-and-oxygen-containing material 325 that may be characterized by improved quality and uniformity compared to conventional technologies. By providing the hydrogen-containing precursor with the oxygen-containing precursor at operation 215 and/or performing the treatment at optional operation 235, method 200 may provide improved silicon-and-oxygen-containing material 325. To characterize the improved quality, the silicon-and-oxygen-containing material 325 may be characterized by a WER of less than or about 12 nm/min. WER may be measured by submersing the substrate 305, including the deposited silicon-and-oxygen-containing material 325, in a 100:1 dHF solution for a period of time, such as about 45 seconds. The WER may be the reduction in thickness of the silicon-and-oxygen-containing material 325 over the period of time, expressed in nm/min. In embodiment, the WER may be less than or about 11.8 nm/min, and may be less than or about 11.6 nm/min, less than or about 11.4 nm/min, less than or about 11.2 nm/min, less than or about 11 nm/min, less than or about 10.8 nm/min, and may be less than or about 10.6 nm/min, less than or about 10.4 nm/min, less than or about 10.2 nm/min, less than or about 10 nm/min, less than or about 9.5 nm/min, less than or about 9 nm/min, less than or about 8.5 nm/min, less than or about 8 nm/min, less than or about 7.5 nm/min, less than or about 7 nm/min, less than or about 6.5 nm/min, less than or about 6 nm/min, less than or about 5.5 nm/min, less than or about 5 nm/min, less than or about 4.5 nm/min, less than or about 4 nm/min, or less. The WER may be measured at any spot along the features 315. However, the present technology may provide silicon-and-oxygen-containing material 325 characterized by the previously-discussed WERs at a deepest part of the features, which indicates the improved quality of the material along the entire length or depth of the features 315.

Relative to conventional technologies, silicon-and-oxygen-containing material 325 of the present technology may be characterized by an increase in quality, again measured by WER. In embodiments, the WER of the silicon-and-oxygen-containing material may be reduced by greater than or about 10%, and may be characterized by an increase in quality of greater than or about 15%, greater than or about 20%, greater than or about 25%, greater than or about 30%, greater than or about 35%, greater than or about 40%, greater than or about 45%, greater than or about 50%, or more. Additionally, the present technology may provide silicon-and-oxygen-containing material 325 with increased uniformity, which may be indicated by a more consistent WER along the entire length or depth of the materials in the features 315.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a silicon-containing precursor” includes a plurality of such precursors, and reference to “the silicon-containing material” includes reference to one or more materials and equivalents thereof known to those skilled in the art, and so forth. “About” and/or “approximately” as used herein when referring to a measurable value such as an amount, a temporal duration, and the like, encompasses variations of ±20% or ±10%, ±5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or +0.1% from the specified value, as such variations are appropriate to in the context of the systems, devices, circuits, methods, and other implementations described herein.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
i) providing a silicon-containing precursor to a processing region of a semiconductor processing chamber, wherein a substrate is disposed within the processing region of the semiconductor processing chamber, and wherein the substrate defines one or more features along the substrate;
ii) contacting the substrate with the silicon-containing precursor, wherein the contacting deposits a silicon-containing material on the substrate, wherein the silicon-containing material extends within the one or more features along the substrate;
iii) providing an oxygen-containing precursor and a hydrogen-containing precursor to the processing region of the semiconductor processing chamber;
iv) forming plasma effluents of the oxygen-containing precursor and the hydrogen-containing precursor;
v) contacting the substrate with the plasma effluents of the oxygen-containing precursor and the hydrogen-containing precursor, wherein the contacting converts the silicon-containing material to a silicon-and-oxygen-containing material, and wherein the contacting increases Si—O—Si crosslinking in the silicon-and-oxygen-containing material; and
repeating operations i through v to iteratively fill the one or more features on the substrate with the silicon-and-oxygen-containing material.

2. The semiconductor processing method of claim 1, wherein the silicon-containing precursor comprises diisopropylaminosilane (DIPAS).

3. The semiconductor processing method of claim 1, wherein the one or more features are characterized by an aspect ratio of greater than or about 10:1.

4. The semiconductor processing method of claim 1, wherein the oxygen-containing precursor comprises diatomic oxygen (O₂).

5. The semiconductor processing method of claim 1, wherein the hydrogen-containing precursor comprises diatomic hydrogen (H₂).

6. The semiconductor processing method of claim 1, wherein a flow rate ratio of the oxygen-containing precursor relative to the hydrogen-containing precursor is between about 20:1 and about 4:1.

7. The semiconductor processing method of claim 1, wherein a temperature within the semiconductor processing chamber is maintained at greater than or about 300° C.

8. The semiconductor processing method of claim 1, wherein a pressure within the semiconductor processing chamber is maintained at less than or about 10 Torr.

9. A semiconductor processing method comprising:
i) providing a silicon-containing precursor to a processing region of a semiconductor processing chamber, wherein a substrate is disposed within the processing region of the semiconductor processing chamber, and wherein the substrate defines one or more features along the substrate;
ii) contacting the substrate with the silicon-containing precursor, wherein the contacting deposits a silicon-containing material on the substrate, wherein the silicon-containing material extends within the one or more features along the substrate;
iii) providing an oxygen-containing precursor to the processing region of the semiconductor processing chamber;
iv) contacting the substrate with the oxygen-containing precursor, wherein the contacting converts the silicon-containing material to a silicon-and-oxygen-containing material;
repeating operations i through iv to iteratively fill the one or more features on the substrate with the silicon-and-oxygen-containing material; and
v) thermally treating the silicon-and-oxygen-containing material with the oxygen-containing precursor and a hydrogen-containing precursor, wherein the treating increases Si—O—Si crosslinking in the silicon-and-oxygen-containing material.

10. The semiconductor processing method of claim 9, wherein treating the silicon-and-oxygen-containing material with the oxygen-containing precursor and the hydrogen-containing precursor is performed for a period of time of greater than or about 5 minutes.

11. The semiconductor processing method of claim 9, wherein treating the silicon-and-oxygen-containing material with the oxygen-containing precursor and the hydrogen-containing precursor reduces a wet etch rate (WER) of the silicon-and-oxygen-containing material by greater than or about 10%.

12. The semiconductor processing method of claim 9, further comprising:
increasing a temperature within the processing region prior to treating the silicon-and-oxygen-containing material with the oxygen-containing precursor and the hydrogen-containing precursor.

13. The semiconductor processing method of claim 9, wherein a temperature is maintained at greater than or about 500° C. while treating the silicon-and-oxygen-containing material with the oxygen-containing precursor and the hydrogen-containing precursor.

14. The semiconductor processing method of claim 9, wherein a pressure within the semiconductor processing chamber is maintained at greater than or about 40 Torr while treating the silicon-and-oxygen-containing material with the oxygen-containing precursor and the hydrogen-containing precursor.

15. A semiconductor processing method comprising:
i) providing a silicon-containing precursor to a processing region of a semiconductor processing chamber, wherein a substrate is disposed within the processing region of the semiconductor processing chamber, and wherein the substrate defines one or more features along the substrate;
ii) contacting the substrate with the silicon-containing precursor, wherein the contacting deposits a silicon-containing material on the substrate, wherein the silicon-containing material extends within the one or more features along the substrate;
iii) providing an oxygen-containing precursor and a hydrogen-containing precursor to the processing region of the semiconductor processing chamber;
iv) forming plasma effluents of the oxygen-containing precursor and the hydrogen-containing precursor;
v) contacting the substrate with the plasma effluents of the oxygen-containing precursor and the hydrogen-containing precursor, wherein the contacting converts the silicon-containing material to a silicon-and-oxygen-containing material, and wherein the contacting increases Si—O—Si crosslinking in the silicon-and-oxygen-containing material;
repeating operations i through v to iteratively fill the one or more features on the substrate with the silicon-and-oxygen-containing material; and
vi) thermally treating the silicon-and-oxygen-containing material with the oxygen-containing precursor and the hydrogen-containing precursor, wherein the treating further increases Si—O—Si crosslinking in the silicon-and-oxygen-containing material.

16. The semiconductor processing method of claim 15, wherein the one or more features are characterized by an aspect ratio of greater than or about 30:1.

17. The semiconductor processing method of claim 15, wherein a flow rate ratio of the oxygen-containing precursor relative to the hydrogen-containing precursor at operation iii) is between about 20:1 and about 4:1.

18. The semiconductor processing method of claim 15, further comprising:
subsequent to filling the one or more features on the substrate with the silicon-and-oxygen-containing material, increasing a temperature within the processing region.

19. The semiconductor processing method of claim 15, further comprising:
subsequent to filling the one or more features on the substrate with the silicon-and-oxygen-containing material, increasing a pressure within the processing region.

20. The semiconductor processing method of claim 15, wherein, subsequent to thermally treating the silicon-and-oxygen-containing material with the oxygen-containing precursor and the hydrogen-containing precursor, the silicon-and-oxygen-containing material is characterized by a wet etch rate (WER) of less than or about 12 nm/min.
